(19) United States
(12) Patent Application Publication
(10) Pub. No.: US 2026/0092371 A1
(43) Pub. Date: Apr. 2, 2026

(54) DUAL CHANNEL SHOWERHEAD

(71) Applicant: Applied Materials, Inc., Santa Clara, CA (US)

(72) Inventors: Joel M. HUSTON, San Jose, CA (US); Vinod Kumar KONDA PURATHE, Bangalore (IN); Peiyu ZHANG, Santa Clara, CA (US); Xiaoxiong YUAN, San Jose, CA (US); Sandesh YADAMANE, Bangalore (IN); Srinivas TOKUR MOHANA, Bangalore (IN)

(21) Appl. No.: 19/345,547

(22) Filed: Sep. 30, 2025

(30) Foreign Application Priority Data
Oct. 1, 2024 (IN) 202441074224

(51) Int. Cl. C23C 16/455

(52) U.S. Cl. CPC C23C 16/45565

(57) ABSTRACT

A showerhead for a semiconductor processing system is provided. In one aspect, a showerhead includes a body that defines a first gas channel formed, at least in part, by injection holes in fluid communication with a distribution cavity in which a plurality of radially-extending ribs of the body define a plurality of radially-extending passages. A first gas is flowable along the first gas channel so that the first gas injected through the injection holes and into the distribution cavity flows radially along the radially-extending passages and so that at least a portion of the first gas flowing along such passages flows through distribution holes extending to a bottom surface of the body. The body also defines a second gas channel formed by a plurality of through holes so that a second gas is flowable therethrough. The first and second gas channels are fluidly isolated from one another within the showerhead.

### CROSS-REFERENCE TO RELATED APPLICATIONS

This application claims priority to Indian provisional application number 202441074224, filed Oct. 1, 2024, which is incorporated herein by reference in its entirety.

### BACKGROUND

### Field

Embodiments of the present disclosure generally relate to semiconductor processing systems, and more particularly, to showerheads for use with semiconductor processing systems.

### Description of the Related Art

In processing semiconductor wafers, such as in a deposition process, it may be beneficial to pulse certain precursors into a processing chamber to expose a wafer to such precursors, and then to quickly switch and pulse other precursors into the processing chamber, all while keeping the reactants of the precursors separate from one another until just above the wafer. Semiconductor processing systems can include showerheads that facilitate distribution of precursors into a processing chamber. Some showerhead designs can provide for fast gas switching to allow different precursors to be pulsed while other showerhead designs can keep reactants of the precursors separate. However, a showerhead design that can provide for fast gas switching and that keeps the reactants of different precursors separate until just above the wafer has proven challenging.

Accordingly, there is a need in the art for a showerhead that addresses the challenges noted above.

### SUMMARY

The present disclosure generally relates to dual-channel showerheads for use with semiconductor processing systems.

In one embodiment, a showerhead for use in a semiconductor processing chamber is provided. The showerhead includes a body having a top surface and a bottom surface. The body defines a first gas channel formed, at least in part, by injection holes in fluid communication with a distribution cavity in which a plurality of radially-extending ribs of the body define a plurality of radially-extending passages. A first gas is flowable along the first gas channel so that the first gas injected through the injection holes and into the distribution cavity flows radially along the plurality of radially-extending passages and so that at least a portion of the first gas flowing along the plurality of radially-extending passages flows through distribution holes extending to the bottom surface. The body also defines a second gas channel formed by a plurality of through holes that extend from the top surface to the bottom surface so that a second gas is flowable therethrough. The first and second gas channels are fluidly isolated from one another within the showerhead.

In another embodiment, a semiconductor processing system is provided. The semiconductor processing system includes a remote plasma region, a processing chamber, and a showerhead at least partially defining the remote plasma region and at least partially defining the processing chamber. The showerhead includes a body having a top surface and a bottom surface. The body defines a first gas channel formed, at least in part, by injection holes in fluid communication with a distribution cavity in which a plurality of radially-extending ribs of the body define a plurality of radially-extending passages. A first gas is flowable along the first gas channel so that the first gas injected through the injection holes and into the distribution cavity flows radially along the plurality of radially-extending passages and so that at least a portion of the first gas flowing along the plurality of radially-extending passages flows through distribution holes into the processing chamber. Further, the body defines a second gas channel formed by a plurality of through holes that extend from the top surface to the bottom surface so that a second gas is flowable therethrough from the remote plasma chamber into the processing chamber. The first and second gas channels are fluidly isolated from one another within the showerhead.

In a further embodiment, a showerhead for use in a semiconductor processing chamber is provided. The showerhead includes a body having a top surface and a bottom surface. The body defines a first gas channel formed, at least in part, a plurality of chord-extending passages defined by a plurality of chord-extending ribs of the body. A first gas is flowable along the first gas channel so that the first gas delivered to the chord-extending passages flows chordwise along the plurality of chord-extending passages and so that at least a portion of the first gas flowing along the chord-extending passages flows through distribution holes extending to the bottom surface. Further, the body defines a second gas channel formed by a plurality of through holes that extend from the top surface to the bottom surface so that a second gas is flowable therethrough. The first and second gas channels are fluidly isolated from one another within the showerhead.

In yet a further embodiment, a method is provided. The method includes flowing a first gas through a first gas channel to a processing chamber of a semiconductor processing system, the first gas channel being defined by a body of a showerhead, and wherein in flowing the first gas through the first gas channel, the first gas injected into a distribution cavity defined by the body flows radially along a plurality of radially-extending passages defined by a plurality of radially-extending ribs of the body, with at least a portion of the first gas flowing radially along the radially-extending passages flowing through distribution holes and to the processing chamber; and flowing a second gas through a second gas channel from a remote plasma region to the processing chamber, the second gas channel being defined as a collection of through holes formed by the body, and wherein the first and second gas channels are fluidly isolated from one another within the showerhead.

In still a further embodiment, a method is provided. The method includes flowing a first gas through a first gas channel to a processing chamber of a semiconductor processing system, the first gas channel being defined by a body of a showerhead, and wherein in flowing the first gas through the first gas channel, the first gas is delivered to a plurality of chord-extending passages defined by a plurality of chord-extending ribs of the body, with at least a portion of the first gas flowing along the chord-extending passages flowing through distribution holes and to the processing chamber; and flowing a second gas through a second gas channel from a remote plasma region to the processing chamber, the second gas channel being defined as a collection of through holes formed by the body, and wherein the first and second gas channels are fluidly isolated from one another within the showerhead.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a schematic, side cross-sectional view of a semiconductor processing system, according to one or more embodiments of the disclosure.

FIG. 2 is a perspective view of an example showerhead with a top side of the showerhead depicted, according to one or more embodiments of the disclosure.

FIG. 3 is a perspective view of the showerhead of FIG. 2, with a bottom side of the showerhead depicted.

FIG. 4 is a perspective view of the showerhead of FIG. 2, with a top side of the core plate of the showerhead revealed.

FIG. 5 is a close-up perspective view of the top side of the core plate detailing an injection region.

FIG. 6 is a close-up, perspective cross-sectional view of the showerhead of FIG. 2.

FIG. 7 is a perspective view of the showerhead of FIG. 2, depicting a bottom side of the core plate of the showerhead.

FIG. 8 is a close-up view of a portion of the showerhead of FIG. 2, depicting the bottom side of the core plate of the showerhead.

FIGS. 9A and 9B are close-up, perspective cross-sectional views of the showerhead of FIG. 2.

FIG. 10 is a perspective view of another example showerhead, according to one or more embodiments of the disclosure.

FIG. 11 is a perspective cross-sectional view of a portion of the showerhead of FIG. 10, depicting distribution holes and through holes thereof.

FIG. 12 is a flow diagram for an example method, according to one or more embodiments of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure provides various embodiments of a dual-channel showerhead for semiconductor processing systems. The dual-channel showerheads disclosed herein, or DCSH, can include dual high conductance gas channels, including a first gas channel and a second gas channel along which a first gas and a second gas can flow, respectively, to a process region for processing a substrate or wafer. The first and second gases can contain different precursors, for example. The dual-channel showerheads of the present disclosure can be arranged so that the channels keep their respective gases separate or fluidly isolated from one another (e.g., so that precursors can be kept separate until just above the substrate in the processing chamber), whilst providing for fast pulsing and switching of the gases, as well as good distribution uniformity of the gases into the processing chamber. The channels can also be arranged so that one of the channels can provide for high radical transport with high ion blocking efficiency.

For instance, in some example aspects, a body of a showerhead can define streamlined internal channels and holes to form the gas channels, and the relatively short internal channels and holes can enable the fast switching and pulsing of the gases through the showerhead, as well as uniform distribution to the processing chamber. For example, a first gas channel of a showerhead can be formed, at least in part, by radial-extending passages or chord-extending passages that facilitate streamlined distribution of the first gas into the processing chamber for processing a substrate. In the case of the radial-extending passages, the first gas can be delivered to a centrally-located injection region via a recursive network of delivery channels, and after being injected, the first gas can flow radially along the radially-extending passages, including in all radial directions from the centrally-located injection region a distance that is less than a radius of the body. In this regard, the first gas can flow in a uniform and streamlined manner along the radially-extending passages, distributing portions of the first gas through distribution holes to the processing chamber along the way. In the case of the chord-extending passages, which can be arranged parallel to one another, the first gas delivered thereto and can “cross flow” in a uniform and streamlined manner along the chord-extending passages, distributing portions of the first gas through distribution holes to the processing chamber along the way. A second gas channel of the showerhead can be formed collectively by a plurality of through holes that extend through the body. The through holes can allow for high radical transport with high ion blocking efficiency.

Accordingly, the showerheads of the present disclosure can advantageously provide fast gas switching and pulsing, uniform distribution of gases to the processing chamber, and high radical transport with high ion blocking efficiency, while keeping the reactants of the gases in the first and second gas channels separate.

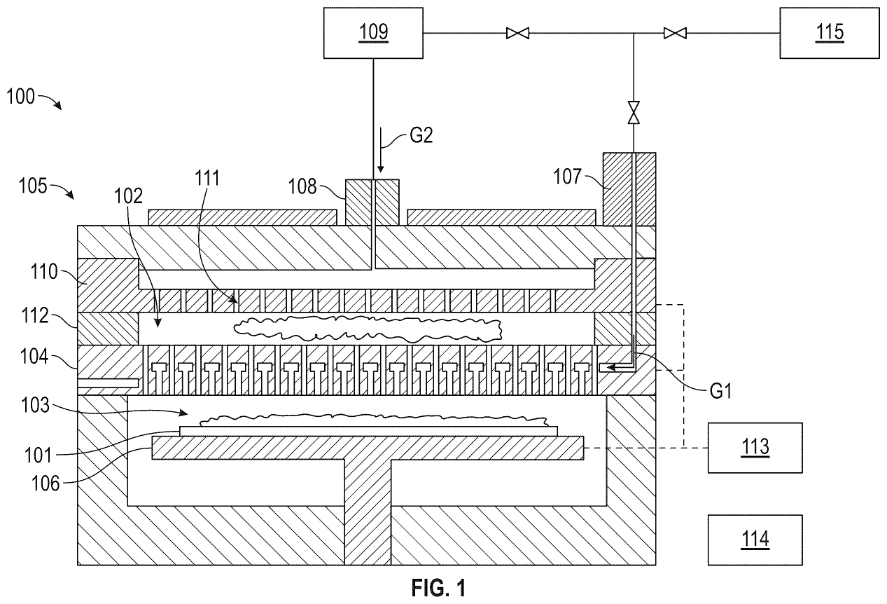

FIG. 1 is a schematic, side cross-sectional view of a semiconductor processing system 100, according to one or more embodiments of the disclosure. The semiconductor processing system 100 can be used to process a substrate 101, such as a semiconductor wafer. For instance, the semiconductor processing system 100 can include features for depositing, annealing, curing and/or etching a dielectric film on the substrate 101.

As illustrated in FIG. 1, the semiconductor processing system 100 has a remote plasma region 102 and a processing chamber 103 separated by a showerhead 104 of a lid assembly 105. The showerhead 104 can be a dual-channel showerhead, for example. The substrate 101 can be disposed on a pedestal 106 within the processing chamber 103. The pedestal 106 may have a heat exchange channel through which a heat exchange fluid flows to control the temperature of the substrate 101, which may be operated to heat and/or cool the substrate 101 during processing operations. The wafer support platter of the pedestal 106, which can be formed of aluminum, ceramic, or a combination thereof, may also be resistively heated in order to achieve relatively high temperatures, such as from up to or about 100° C. to above or about 1100° C., using an embedded resistive heater element.

During processing of the substrate 101, such as during a deposition or etching process, process gases can be delivered to the lid assembly 105 and ultimately to the processing chamber 103 by way of a fluid supply system 115, which can include one or more fluid supplies, fluid conduits, and valves. The fluid supplies can contain gases of various elements (or combinations of elements) and the valves can be controlled so that a gas containing certain elements or some mixture thereof can be selectively supplied for processing the substrate 101.

For instance, a first process gas G1 can be selectively directed into a first manifold 107, or side feed manifold, and directed into a first gas channel of the showerhead 104 as shown in FIG. 1. A portion of the first process gas G1 flowing through the first gas channel of the showerhead 104 can flow into the processing chamber 103 while the other portion can be exhausted from the showerhead 104 and discarded. Notably, the first process gas G1 can bypass a remote plasma system (RPS), or RPS 109, as well as the remote plasma region 102.

A second process gas G2 can be selectively directed into the remote plasma region 102 through a second manifold 108, or center feed manifold. The RPS 109 can process the second process gas G2, which then travels through the second manifold 108, through a faceplate 110, or rather, through a plurality of faceplate holes 111 of the faceplate 110, and into the remote plasma region 102. By passing the second process gas G2 having plasma generating gases and/or plasma excited species through the faceplate holes 111, depending on use of the RPS 109, a more uniform delivery into the remote plasma region 102 may be provided. The showerhead 104 may distribute the second process gas G2 containing plasma effluents upon excitation by a plasma in the remote plasma region 102 or from the RPS 109. In some embodiments, the second process gas G2 introduced into the RPS 109 and/or remote plasma region 102 may contain fluorine, e.g., CF₄, NF₃, or XeF₂, oxygen, e.g., N₂O, or hydrogen-containing precursors, e.g., H₂ or NH₃. One or both process gases G1, G2 may also include a carrier gas, such as helium (He), argon (Ar), nitrogen (N₂), etc. Plasma effluents may include ionized or neutral derivatives and may also be referred to herein as a radical-fluorine precursor, referring to the atomic constituent of the process gas introduced. In an example, a fluorine-containing gas, such as NF₃, may be excited in the RPS 109 and passed through the remote plasma region 102 without the additional generation of plasma in that region. Plasma effluents from the RPS 109 may pass through the second gas channel of the showerhead 104 and then react with the substrate 101. After passing through the showerhead 104, plasma effluents may include radical species and may be essentially devoid of ionic species or UV light. These plasma effluents may react with films on the substrate 101, e.g., titanium nitride and other masking material.

An insulating ring 112 or isolator can be disposed between the faceplate 110 and the showerhead 104 to allow an AC potential to be applied to the faceplate 110 relative to the showerhead 104. The insulating ring 112 may be positioned between the faceplate 110 and the showerhead 104 to enable a capacitively coupled plasma (CCP) to be formed in the remote plasma region 102. Particularly, the processing system can include a power supply 113 electrically coupled with the processing chamber 103 to provide electric power to the faceplate 110, the showerhead 104, and/or the pedestal 106 to generate a plasma in the remote plasma region 102 or processing chamber 103. The power supply 113 may be configured to deliver an adjustable amount of power to the processing chamber 103 depending on the process performed. Such a configuration may allow for a tunable plasma to be used in the processes being performed.

A plasma may be ignited either in the remote plasma region 102 above the showerhead 104 or in the processing chamber 103 below the showerhead 104, as illustrated in FIG. 1. In some embodiments, the plasma formed in processing chamber 103 may be a DC-biased plasma formed with the pedestal 106 acting as an electrode. Plasma may be present in the remote plasma region 102 to produce the radical precursors from an inflow of, for example, a fluorine-containing precursor or other precursor. An AC voltage typically in the radio frequency (RF) range may be applied between the faceplate 110 (or other conductive top portion of the lid assembly 105) and the showerhead 104 to ignite a plasma in the remote plasma region 102 during deposition. An RF power supply may generate a high RF frequency of 13.56 MHz but may also generate other frequencies alone or in combination with the 13.56 MHz frequency.

The semiconductor processing system 100 can include a controller 114 for controlling various controllable devices thereof, such as the valves of the fluid supply system 115, the RPS 109, the power supply 113, etc. The controller 114 can be communicatively coupled with the controllable devices, e.g., by one or more wired or wireless communication links. The controller 114 can include one or more processors and one or more memory devices, such as one or more non-transitory memory devices. The one or more memory devices can store information accessible by the one or more processors, including a program that can be executed by the one or more processors. When the program is executed by any combination of the one or more processors, the one or more processors can perform an operation, such as a deposition process. The program can be software written in any suitable programming language or can be implemented in hardware. The memory devices can also store data that can be accessed by the processors. For example, the data can include one or more table(s), function(s), algorithm(s), model(s), equation(s), libraries, etc. according to example aspects of the present disclosure. The controller 114 can include a communication interface used to communicate with other components, including the controllable devices. The communication interface can include any suitable components for interfacing with other components, including transmitters, receivers, ports, controllers, antennas, etc.

As noted above, the showerhead 104 can be a dual-channel showerhead. The showerhead 104 can include dual high conductance gas channels that are fluidly isolated from one another (e.g., so that precursors can be kept separate until just above the substrate 101 in the processing chamber 103), whilst providing for fast pulsing and switching of the process gases G1, G2 as well as good distribution uniformity of the gases G1, G2 to the processing chamber 103. Further, one of the gas channels of the showerhead 104 can provide high radical transport with high ion blocking efficiency. The showerhead 104 can be constructed in accordance with one of the example embodiments of showerheads provided below.

### Radial Flow Showerhead

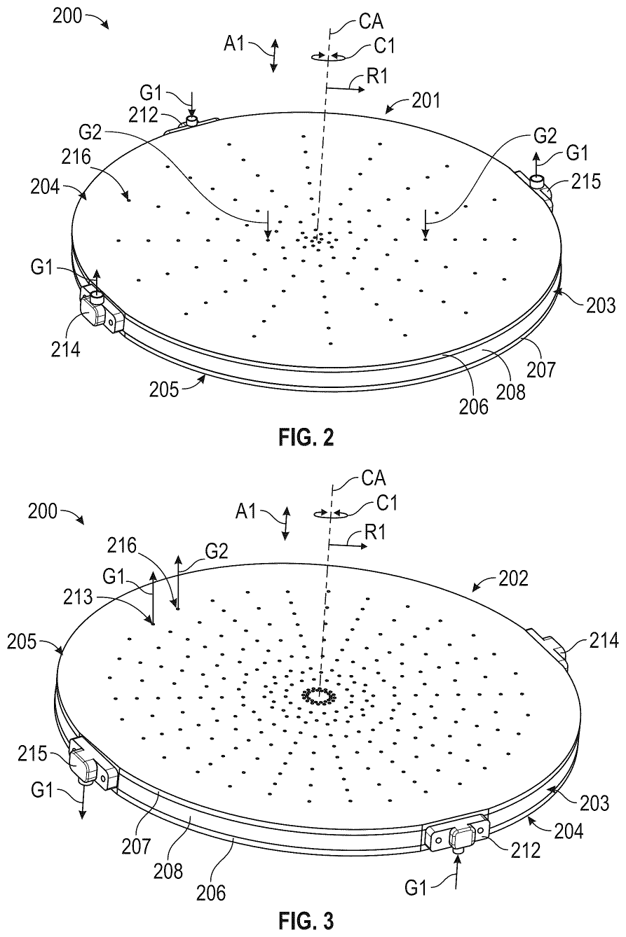

With reference now to FIGS. 2 and 3, perspective views of an example showerhead 200 are depicted, according to one or more embodiments of the disclosure. The showerhead 200 can be implemented in a semiconductor processing system, such as the semiconductor processing system 100 of FIG. 1. The showerhead 200 of FIGS. 2 and 3 is configured as a “dual-channel radial flow showerhead”, which, as will explained below, includes dual gas channels, with one of the gas channels including radially-extending passages along which a gas is flowable. For reference, the showerhead 200 defines an axial direction A1, a radial direction R1, and a circumferential direction C1. The showerhead 200 also defines a center axis CA, which extends parallel with the axial direction A1.

In FIG. 2, a top side 201 of the showerhead 200 is illustrated while a bottom side 202 of the showerhead 200 is shown in FIG. 3. Accordingly, in FIG. 2, the showerhead 200 is right-side up while in FIG. 3 the showerhead 200 is up-side down. As depicted in FIGS. 2 and 3, the showerhead 200 has a body 203 having a top surface 204 and a bottom surface 205. In at least some example embodiments, the body 203 can be formed by a stacked arrangement of plates, including a top plate 206, a bottom plate 207, and a core plate 208 disposed between the top plate 206 and the bottom plate 207, e.g., along the axial direction A1. The plates can be bonded together to form the body 203. For instance, the top plate 206 can be bonded to the core plate 208 and the bottom plate 207 can be bonded to the core plate 208. The plates can be diffusion bonded to form the body 203, for example. The plates can be formed of aluminum and coated with aluminum oxide, e.g., via atomic layer deposition. In further embodiments, the body 203 can be formed as a unitary, monolithic component, e.g., by an additive manufacturing process.

The top surface 204 of the body 203 is formed by the top plate 206 while the bottom surface 205 of the body 203 is formed by the bottom plate 207. In some embodiments, the showerhead 200 can at least partially define a remote plasma region and can at least partially define a processing chamber, e.g., as shown in FIG. 1. For instance, the top surface 204 of the body 203 can at least partially define the remote process chamber while the bottom surface 205 of the body 203 can at least partially define the processing chamber in which a substrate is processed.

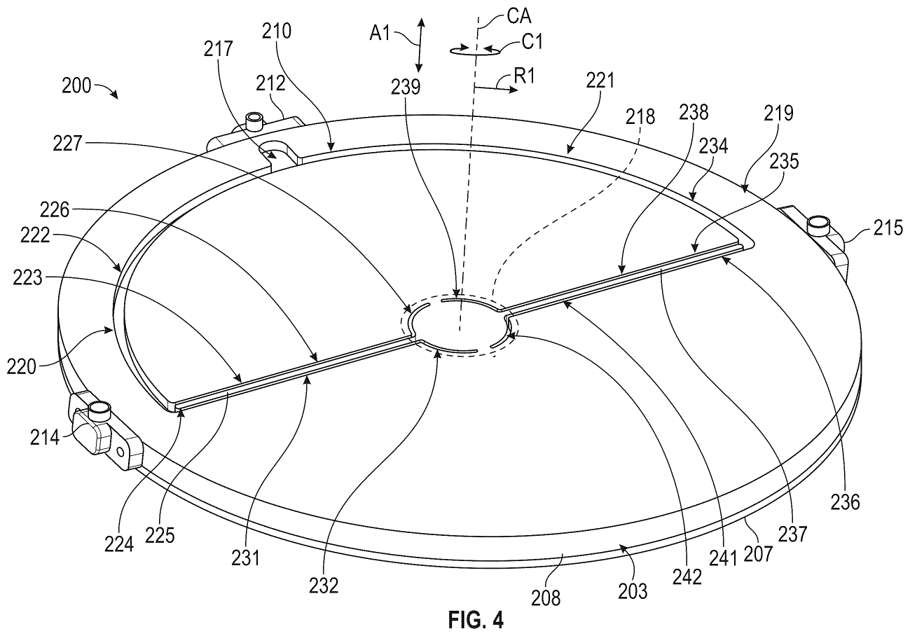

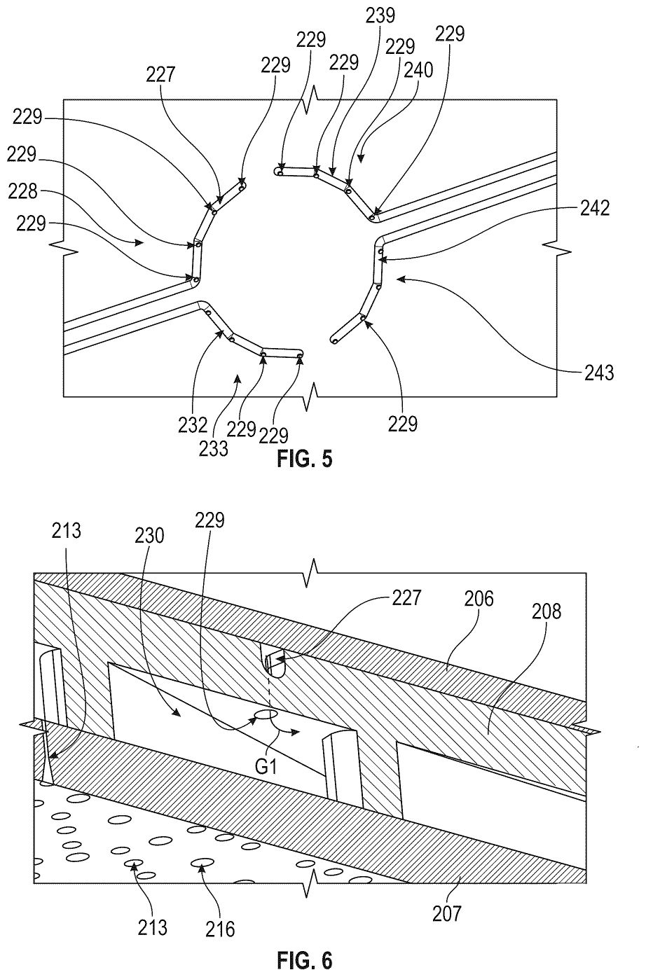

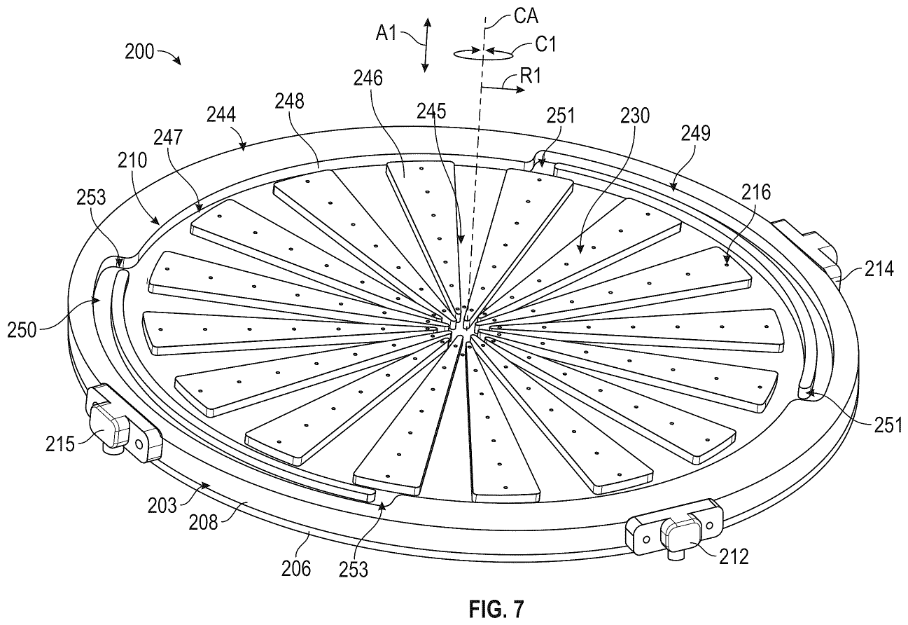

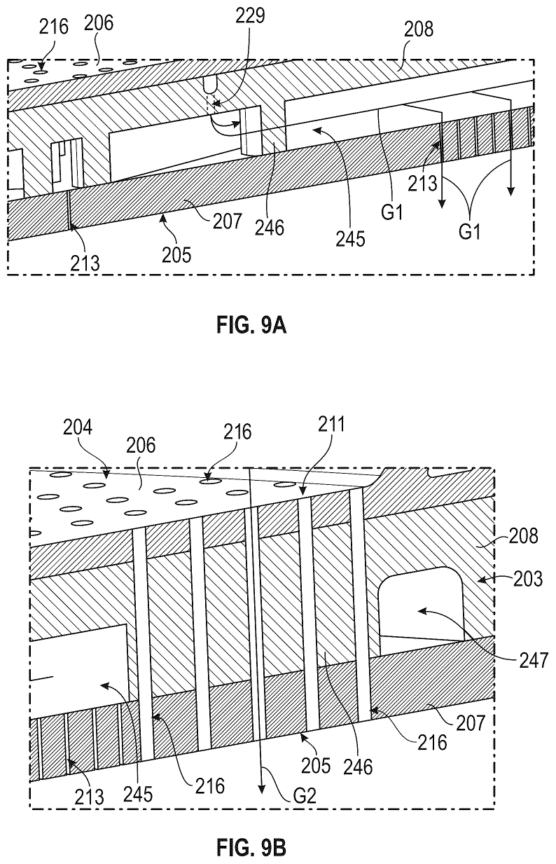

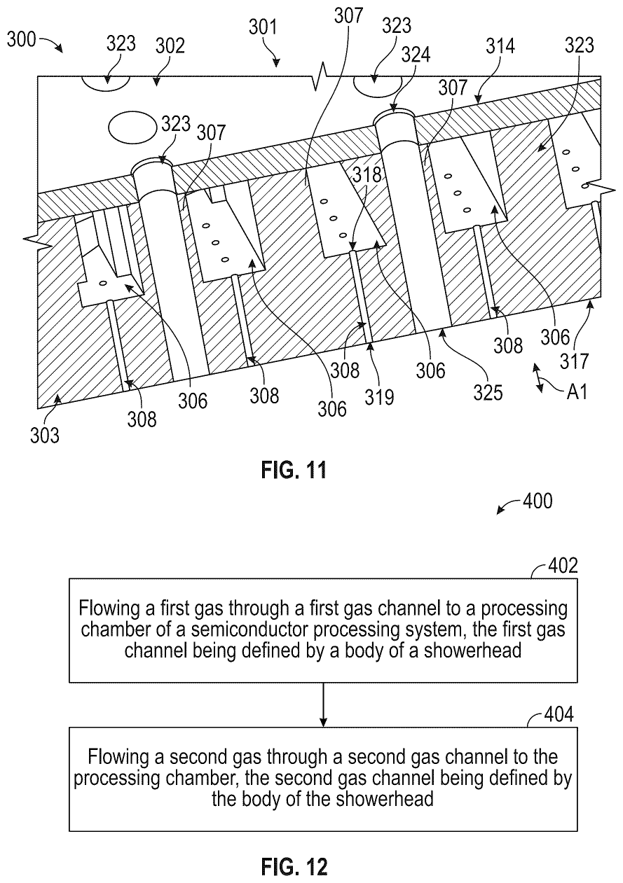

Generally, a first gas G1 can flow through the showerhead 200 along a first gas channel 210 (FIG. 4) and a second gas G2 can flow through the showerhead 200 along a second gas channel 211 (FIG. 11), with the first and second gas channels 210, 211 being fluidly isolated from one another. In this way, reactants in the first and second gases G1, G2 can be kept separate. The first gas G1 can enter the showerhead 200 by way of an inlet port 212. The first gas G1 can flow along the first gas channel 210, and a portion of the first gas G1 can exit the showerhead 200 through distribution holes 213 (see also FIGS. 6 and 9) defined by the bottom plate 207 and can flow, e.g., into a processing chamber for processing a substrate. Further, a portion of the first gas G1 flowing along the first gas channel 210 can exit the showerhead 200 by way of a first outlet port 214 or a second outlet port 215. The portion of the first gas G1 flowing out of the first outlet port 214 or the second outlet port 215 can be discarded, for example. The second gas G2 can pass through the showerhead 200 by way of a plurality of through holes 216 (see also FIG. 9B) that extend from the top surface 204 to the bottom surface 205 of the body 203 so that the second gas G2 is flowable therethrough, e.g., from the remote plasma region to the processing chamber for processing a substrate.

In FIG. 2, the inlets of the through holes 216 are shown, while the outlets of the through holes 216 are illustrated in FIG. 3. There is a greater number of holes defined by the bottom plate 207 as depicted in FIG. 3 than the top plate 206 in FIG. 2, namely because only the through holes 216 (or inlets thereof) are depicted in FIG. 2 while the through holes 216 (or outlets thereof) and the distribution holes 213 (or outlets thereof) are depicted in FIG. 3. In this regard, the distribution holes 213 do not extend through the axial thickness of the body 203, but rather, through the bottom plate 207 (e.g., as shown in FIGS. 6 and 9).

The first gas channel 210 along which the first gas G1 flows will now be described in greater detail. The first gas channel 210 has a first stage and a second stage. In the first stage, or delivery stage, the first gas G1 is delivered to an injection region via a recursive network of delivery passages. At the injection region, the first gas G1 is injected into a distribution cavity. In the second stage, or distribution stage, the first gas G1 injected into the distribution cavity flows radially along radially-extending passages. A first portion of the first gas G1 flowing along the radially-extending passages can flow into the distribution holes 213 (FIG. 9A), e.g., and to a processing chamber for processing of a substrate, and a second portion of the first gas G1 flowing along the radially-extending passages can be collected at an outer periphery of the distribution cavity and ultimately directed out of the showerhead 200 via the first and second outlet ports 214, 215.

As shown in FIG. 4, the first stage of the first gas channel 210 defined by the body 203 is formed by an inlet plenum 217 and recursive delivery passages that deliver the first gas G1 to an injection region 218 of the body 203. For this embodiment, the injection region 218 is arranged at a central region of the body 203, e.g., with the central region encompassing an area extending radially outward from the center axis CA and swept by a radius that is less than one sixth a radius of the body 203. The inlet plenum 217 and the delivery passages can be formed by or recessed into a top surface 219 of the core plate 208, for example. When the top plate 206 (see FIG. 2; the top plate 206 is not shown in FIG. 4) is disposed on or bonded with the core plate 208, the inlet plenum 217 and the delivery passages can be enclosed to form internal passages.

The inlet plenum 217 is in fluid communication with the inlet port 212. In this way, the first gas G1 flowing into the showerhead 200 through the inlet port 212 can flow into the inlet plenum 217. For the depicted embodiment of FIG. 4, the recursive network of delivery passages includes a first delivery passage 220 and a second delivery passage 221, which are both in fluid communication with the inlet plenum 217. A first portion of the first gas G1 can flow from the inlet plenum 217 into the first delivery passage 220 and a second portion of the first gas G1 can flow from the inlet plenum 217 into the second delivery passage 221. Accordingly, a first recursion or splitting of the first gas G1 takes place at the intersection of the inlet plenum 217 and the first and second delivery passages 220, 221.

The first delivery passage 220 includes a first leg 222, a second leg 223, and a third leg 224. The first leg 222 of the first delivery passage 220 extends from the inlet plenum 217 circumferentially around an outer periphery of the array of the through holes 216 as shown in FIG. 4. For this embodiment, the first leg 222 arcs approximately ninety degrees (90°). The first delivery passage 220 then splits into two legs by a first splitter rib 225 of the body 203, or more particularly, into the second leg 223 and the third leg 224. Accordingly, a recursion or splitting of the first portion of the first gas G1 takes place at the intersection of the first leg 222 and the second and third legs 223, 224 of the first delivery passage 220. That is, the first portion of the first gas G1 can be split into a first injection portion and a second injection portion, with the first injection portion flowing along the second leg 223 and the third injection portion flowing along the third leg 224.

The second leg 223 of the first delivery passage 220 includes a radial section 226 and an injection section 227. The radial section 226 of the second leg 223 is in fluid communication with the first leg 222 and extends lengthwise along the radial direction R1 through the array of through holes 216 as shown in FIG. 4 and to the injection region 218. The injection section 227 is in fluid communication with the radial section 226 and extends along the circumferential direction C1, e.g., approximately eighty-five degrees (85°). As illustrated in FIG. 5, a first set 228 of injection holes 229 are arranged along the injection section 227. The first injection portion of the first gas G1 can flow along the radial section 226 and into the injection section 227, where the first gas G1 is injected into a distribution cavity 230 (FIG. 7) by way of the injection holes 229 of the first set 228. FIG. 6 shows a close-up view of the first gas G1, or the first injection portion thereof, being injected into the distribution cavity 230 by way of one of the injection holes 229 of the first set 228. While there are four (4) injection holes 229 in the first set 228, in other embodiments the first set 228 can include more or less than four (4) injection holes.

Similarly, the third leg 224 of the first delivery passage 220 includes a radial section 231 and an injection section 232. The radial section 231 of the third leg 224 is in fluid communication with the first leg 222 and extends lengthwise along the radial direction R1 through the array of through holes 216 as shown in FIG. 4 and to the injection region 218. The injection section 232 is in fluid communication with the radial section 231 and extends along the circumferential direction C1, e.g., approximately eighty-five degrees (85°). The injection section 232 of the third leg 224 extends in an opposite direction along the circumferential direction C1 than does the injection section 227 of the second leg 223. As illustrated in FIG. 5, a second set 233 of injection holes 229 are arranged along the injection section 232. The second injection portion of the first gas G1 can flow along the radial section 231 and into the injection section 232, where the first gas G1 is injected into the distribution cavity 230 (FIG. 7) by way of the injection holes 229 of the second set 233. While there are four (4) injection holes 229 in the second set 233, in other embodiments the second set 233 can include more or less than four (4) injection holes. In some embodiments, the first and second sets 228, 233 each have a same number of injection holes.

The second delivery passage 221 is configured in a similar manner as the first delivery passage 220. Particularly, the second delivery passage 221 includes a first leg 234, a second leg 235, and a third leg 236. The first leg 234 of the second delivery passage 221 extends from the inlet plenum 217 circumferentially around an outer periphery of the array of the through holes 216 as shown in FIG. 4. For this embodiment, the first leg 234 arcs approximately ninety degrees (90°), e.g., in a direction opposite the first leg 222 of the first delivery passage 220. The second delivery passage 221 then splits into two legs by a second splitter rib 237 of the body 203, or more particularly, into the second leg 235 and the third leg 236. Accordingly, a recursion or splitting of the second portion of the first gas G1 takes place at the intersection of the first leg 234 and the second and third legs 235, 236 of the second delivery passage 221. That is, the first portion of the first gas G1 can be split into a third injection portion and a fourth injection portion, with the third injection portion flowing along the second leg 235 and the fourth injection portion flowing along the third leg 236.

The second leg 235 of the second delivery passage 221 includes a radial section 238 and an injection section 239. The radial section 238 of the second leg 235 is in fluid communication with the first leg 234 and extends lengthwise along the radial direction R1 through the array of through holes 216 as shown in FIG. 4 and to the injection region 218. The injection section 239 is in fluid communication with the radial section 238 and extends along the circumferential direction C1, e.g., approximately eighty-five degrees (85°). As illustrated in FIG. 5, a third set 240 of injection holes 229 are arranged along the injection section 239. The third injection portion of the first gas G1 can flow along the radial section 238 and into the injection section 239, where the first gas G1 is injected into the distribution cavity 230 (FIG. 7) by way of the injection holes 229 of the third set 240. While there are four (4) injection holes 229 in the third set 240, in other embodiments the third set 240 can include more or less than four (4) injection holes.

Similarly, the third leg 236 of the second delivery passage 221 includes a radial section 241 and an injection section 242. The radial section 241 of the third leg 236 is in fluid communication with the first leg 234 and extends lengthwise along the radial direction R1 through the array of through holes 216 as shown in FIG. 4 and to the injection region 218. The injection section 242 is in fluid communication with the radial section 241 and extends along the circumferential direction C1, e.g., approximately eighty-five degrees (85°). The injection section 242 of the third leg 236 extends in an opposite direction along the circumferential direction C1 than does the injection section 239 of the second leg 235. As illustrated in FIG. 5, a fourth set 243 of injection holes 229 are arranged along the injection section 242. The fourth injection portion of the first gas G1 can flow along the radial section 241 and into the injection section 242, where the first gas G1 is injected into the distribution cavity 230 (FIG. 7) by way of the injection holes 229 of the fourth set 243. While there are four (4) injection holes 229 in the fourth set 243, in other embodiments the fourth set 243 can include more or less than four (4) injection holes. In some embodiments, the third and fourth sets 240, 243 each have a same number of injection holes. In some other embodiments, the first, second, third, and fourth sets 228, 233, 240, 243 each have a same number of injection holes.

Accordingly, to summarize the flow of the first gas G1 through the first stage of the first gas channel 210, the first gas G1 is successively split into portions and delivered in a uniform manner to the injection region 218 by the first and second delivery passages 220, 221. At the injection region 218, the first gas G1 is injected into the distribution cavity 230 by way of the injection holes 229. As the distribution cavity 230 is arranged to direct the first gas G1 radially outward with respect to the center axis CA, as will be explained more fully below, the centrally located and circumferentially arranged injection holes 229 can facilitate a more uniform radial flow of the first gas G1 within the distribution cavity 230.

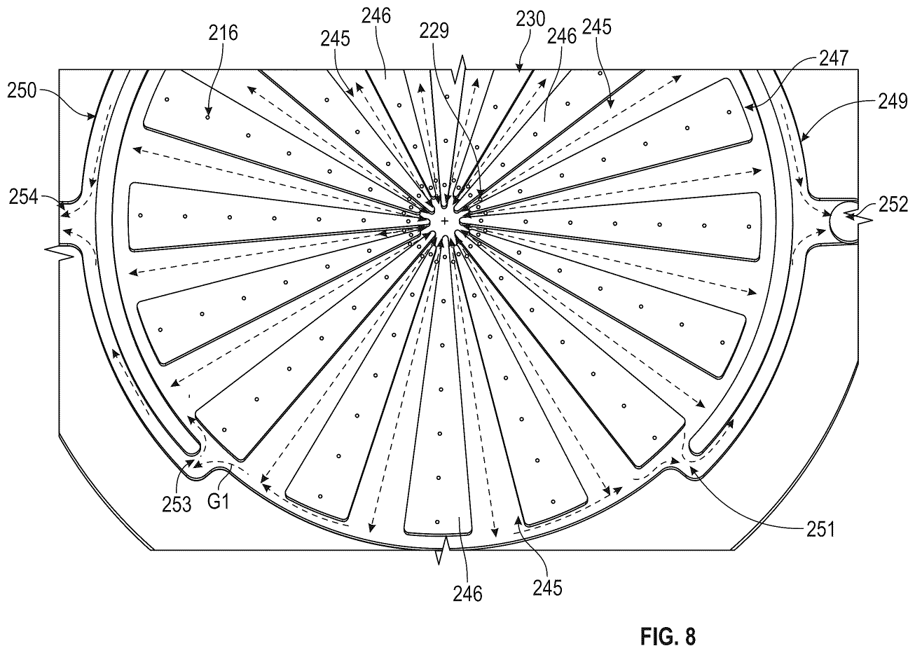

With reference now to FIGS. 7 and 8, the second phase, or distribution phase, of the first gas channel 210 will be described. In FIGS. 7 and 8, the bottom plate 207 (FIG. 3) has been removed for illustrative purposes, and the showerhead 200 is shown upside down.

As shown in FIG. 7, the second stage of the first gas channel 210 defined by the body 203 is formed by the distribution cavity 230. The distribution cavity 230 can be formed by or recessed into a bottom surface 244 of the core plate 208, for example. When the bottom plate 207 (see FIG. 3; the bottom plate 207 is not shown in FIG. 7 or FIG. 8) is disposed on or bonded with the core plate 208, the distribution cavity 230 can be an enclosed internal cavity. For the depicted embodiment of FIGS. 7 and 8, the distribution cavity 230 is circular in shape and has a plurality of radially-extending passages 245 formed by radially-extending ribs 246 of the body 203. Each radially-extending passage 245 is associated with one of the injection holes 229. In this regard, for this embodiment, there are sixteen (16) radially-extending passages 245 because there are sixteen (16) injection holes 229, e.g., as shown in FIG. 8.

The radially-extending ribs 246 are arranged in an annular array around the center axis CA defined by the showerhead 200. As depicted in FIGS. 7 and 8, the radially-extending ribs 246 are circumferentially spaced from one another, have an axial height spanning an axial height of the distribution cavity 230 (see FIGS. 9A and 9B), and have their respective long axes extending radially with respect to the center axis CA. That is, the radially-extending ribs 246 are arranged so as to have their respective long axes extend along the radial direction R1. In some embodiments, the radially-extending ribs 246 can have differing radial lengths. The through holes 216 that collectively define the second gas channel 211 can extend through the radially-extending ribs 246. FIG. 9B shows a set of through holes 216 extending through one of the radially-extending ribs 246.

In some embodiments, the radially-extending ribs can be arranged so that the first gas G1 flowing radially outward along the radially-extending passages 245 to the exhaust plenum 247 is successively split. In this way, the radially-extending passages 245 can be arranged as a recursive network of radially-extending passages. In this way, the first gas G1 can be uniformly received into the annulus of the exhaust plenum 247, or rather, can be more evenly distributed to the exhaust plenum 247 along the circumferential direction C1.

The distribution holes 213 formed by the bottom plate 207 are arranged in fluid communication with the radially-extending passages 245. In some embodiments, the distribution holes 213 can vary in diameter along their respective long axes, which extend along the axial direction A1 in this example embodiment. For instance, the diameters of the distribution holes 213 at their respective outlets can be larger than the diameters of the distribution holes 213 at their respective inlets. In this way, the velocity of the first gas G1 can be decreased as the first gas G1 flows axially through the distribution holes 213. In other embodiments, the distribution holes 213 can have a same or constant diameter along their respective long axes, e.g., as shown in FIGS. 9A and 9B. The distribution holes 213 can be arranged to extend parallel to the axial direction A1 or can be angled with respect to the axial direction A1.

Each radially-extending passage 245 can have a set of the distribution holes 213 each in fluid communication therewith. The set of the distribution holes 213 can be radially spaced from one another along the radial length of a given radially-extending passage 245. FIG. 9A shows a set of the distribution holes 213 in fluid communication with one of the radially-extending passages 245. Some of the volume of the first gas G1 flowing along the radially-extending passages 245 can flow through the distribution holes 213, e.g., and into a processing chamber for processing of a substrate. While a majority of the distribution holes 213 associated with one of the radially-extending passages 245 can be arranged radially outward of the injection holes 229, or rather, radially outward of the injection region 218 (FIG. 4), one or more of the distribution holes 213 associated with the radially-extending passages 245 can be arranged radially inward of the injection holes 229. For instance, in FIG. 9A, one of the distribution holes 213 associated with one of the radially-extending passages 245 is shown arranged radially inward of the injection holes 229.

As further shown in FIGS. 7 and 8, the distribution cavity 230 also has an exhaust plenum 247 arranged at an outer periphery thereof. The exhaust plenum 247 extends circumferentially around the array of the radially-extending ribs 246 and has a radial width defined between a wall 248 (or edge thereof) of the body 203 defining an outer perimeter of the distribution cavity 230 and radially outermost ends of the radially-extending ribs 246. The volume of first gas G1 that does not flow into the distribution holes 213 can flow into the exhaust plenum 247, where the first gas G1 can then flow to an exhaust passage, such as either a first exhaust passage 249 or a second exhaust passage 250.

The first exhaust passage 249 can be formed by the bottom surface 244 of the core plate 208. The first exhaust passage 249 extends circumferentially and includes inlets 251 that provide fluid communication between the first exhaust passage 249 and the exhaust plenum 247. A first outlet plenum 252 is arranged midway along the first exhaust passage 249. The first outlet plenum 252 is in fluid communication with the first outlet port 214. In this way, the first gas G1 collected by the exhaust plenum 247 can flow into the first exhaust passage 249 through the inlets 251 and can flow along the first exhaust passage 249 to the first outlet plenum 252. The first gas G1 can then move from the first outlet plenum 252 to the first outlet port 214, which can exhaust the first gas G1 from the showerhead 200.

The second exhaust passage 250 is configured in a similar manner as the first exhaust passage 249 and is generally arranged radially opposite the first exhaust passage 249. The second exhaust passage 250 can be formed by the bottom surface 244 of the core plate 208. The second exhaust passage 250 extends circumferentially and includes inlets 253 that provide fluid communication between the second exhaust passage 250 and the exhaust plenum 247. A second outlet plenum 254 is arranged midway along the second exhaust passage 250. The second outlet plenum 254 is in fluid communication with the second outlet port 215. In this way, the first gas G1 collected by the exhaust plenum 247 can flow into the second exhaust passage 250 through the inlets 253 and can flow along the second exhaust passage 250 to the second outlet plenum 254. The first gas G1 can then move from the second outlet plenum 254 to the second outlet port 215, which can exhaust the first gas G1 from the showerhead 200.

Accordingly, to summarize the flow of the first gas G1 through the second stage of the first gas channel 210, the first gas G1 is injected into the distribution cavity 230 by way of the injection holes 229. The injection holes 229 are arranged in a circumferential array in the injection region 218, or central region of the body 203, so that the first gas G1 injected into the distribution cavity 230 is injected in a uniform manner into the radially-extending passages 245, which facilitates uniform distribution of the first gas G1 within the distribution cavity 230. Once injected into the distribution cavity 230, the first gas G1 flows radially along the radially-extending passages 245. A portion of the first gas G1 flows radially inward toward the center axis CA, e.g., as shown in FIG. 8, which can then flow into distribution holes 213 arranged radially inward of the injection holes 229. A portion of the first gas G1, or rather a majority thereof, can flow radially outward away from the center axis CA, e.g., as shown in FIG. 8. As the first gas G1 flows radially outward respectively along the radially-extending passages 245, some of the first gas G1 can flow into the distribution holes 213 arranged radially outward of the injection holes 229. The distribution holes 213 can be arranged concentrically around the center axis CA of the body 203 and can be aligned with the radially-extending passages 245. In this way, the first gas G1 can be distributed evenly within a processing chamber arranged below the showerhead 200. Each of the holes shown in FIG. 3 that are not shown in FIG. 2 are the distribution holes 213. In addition, some of the first gas G1 flowing radially-outward along the radially-extending passages 245 can flow to the exhaust plenum 247.

A uniform flow of the first gas G1 to the distribution holes 213 and into the exhaust plenum 247 can be achieved by the annular array of circumferentially-spaced, radially-extending ribs 246 that define the radially-extending passages 245. The first gas G1 can flow radially outward along the radially-extending passages 245 (or sixteen (16) different radially-extending paths in this example), from the injection region 218 (FIG. 4). The first gas G1 received in the exhaust plenum 247 can flow circumferentially to either the first exhaust passage 249 or the second exhaust passage 250. The first gas G1 received within the first and second exhaust passages 249, 250 can then be received by the first and second outlet plenums 252, 254, respectively, and can then exit the showerhead 200 through the first and second outlet ports 214, 215.

The second gas channel 211 along which the second gas G2 flows will now be described in greater detail with reference to FIG. 9B. The second gas channel 211 is collectively formed by the through holes 216. Generally, the through holes 216 allow the second gas G2, which can be different from the first gas G1 (or can include different precursors), to travel through the showerhead 200 in a fluidly separate channel from the first gas G1, e.g., from a remote plasma region to a processing chamber for processing a substrate.

As depicted in FIG. 9B, the through holes 216 extend from the top surface 204 of the body 203 to the bottom surface 205 of the body 203, or rather, through the body 203. The through holes 216 can be arranged concentrically around the center axis CA (FIG. 2) of the body 203 and can be aligned with, and can extend through, each of the radially-extending ribs 246. As shown in FIGS. 7 and 8, for example, a set of the through holes 216 can extend through each one of the radially-extending ribs 246. Accordingly, the sets of through holes, or radial sets, are circumferentially spaced from one another in a similar manner as the array of radially-extending ribs 246, e.g., as shown in FIG. 2. In other embodiments, the radially-extending ribs 246 can each have more or less through holes extending therethrough than in the depicted example embodiment.

In embodiments in which the body 203 is formed by the top plate 206, the bottom plate 207, and the core plate 208 axially disposed therebetween, each one of the through holes 216 can extend through the top plate 206, through the core plate 208, and through the bottom plate 207. The through holes 216 can be pre-formed in the plates prior to their bonding together, or alternatively, the through holes 216 can be formed after the plates have been bonded together. In embodiments in which the body 203 is formed as a unitary monolithic component, such as during a 3D printing process or other additive manufacturing technique, the through holes 216 can be formed through the axial thickness of the body 203.

In some embodiments, the through holes 216 can have a same or constant diameter along their respective long axes, which extend along the axial direction A1 in the illustrated embodiment of FIG. 9B. In other embodiments, the through holes 216 can vary in diameter along their respective long axes. In yet other embodiments, the through holes 216, or a portion thereof, can be angled with respect to the axial direction A1.

To summarize the flow of the second gas G2 through the second gas channel 211, the second gas G2 flows through the through holes 216, e.g., from a remote plasma region to a processing chamber to expose a substrate within the processing chamber to precursors of the second gas G2.

To conclude, with reference generally to FIGS. 2 through 9B, the radial flow, dual-channel showerhead 200 disclosed herein can provide certain advantages and benefits. For instance, while keeping the reactants of the first and second gases G1, G2 separate in their respective first and second gas channels 210, 211, the radially-extending passages 245 of the first gas channel 210 allow the first gas G1 to flow from a centrally-located region and to the distribution holes 213 in a streamlined manner, with the first gas G1 only needing to flow less than a radius of the body 203 to distribute the first gas G1 to the distribution holes 213, which can then flow to a processing chamber for processing a substrate. The first gas G1 can also flow in all radial direction in a uniform manner to the distribution holes 213, which in turn allows for, e.g., uniform distribution of the first gas G1 to the processing chamber. Moreover, when pulsing and switching the first and second gases G1, G2, the first gas G1 can be pulsed into the showerhead 200, and the streamlined radially-extending passages 245 can shorten the distance the first gas G1 flows through the showerhead 200 to the processing chamber, compared to conventional showerheads. And, when the second gas G2 is to be pulsed, the first gas G1 within the first gas channel 210 can be discharged therefrom in a relatively short time period (e.g., by coordinating opening and closing of inlet and outlet valves), once again due to the streamlined radially-extending passages 245 that offer relatively short fluid paths for the first gas G1 to flow. Once the first gas G1 is discharged, the second gas G2 can be directed through the through holes 216, which are also streamlined due to their direct region-to-chamber, axially-extending arrangement. The second gas G2 directed through the through holes 216 can flow into a processing chamber, where the precursors thereof can be used to process the substrate. The through holes 216 can offer high radical transport with high ion blocking efficiency. The switching and pulsing of the first and second gases G1, G2 can continue in the manner described above.

### Cross Flow Showerhead

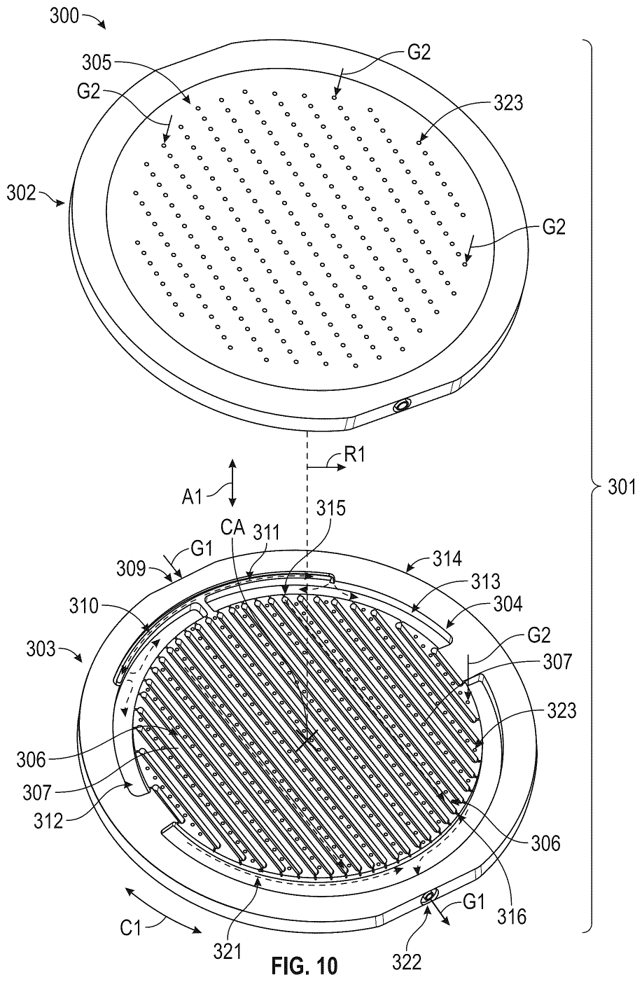

With reference now to FIG. 10, a perspective exploded view of an example showerhead 300 is depicted, according to one or more embodiments of the disclosure. The showerhead 300 can be implemented in a semiconductor processing system, such as the semiconductor processing system 100 of FIG. 1. In FIG. 10, the showerhead 300 is configured as a “dual-channel cross flow showerhead”, which, as will explained below, includes dual gas channels, with one of the gas channels including chord-extending passages along which a gas is flowable. For reference, the showerhead 300 defines an axial direction A1, a radial direction R1, and a circumferential direction C1. The showerhead 300 also defines a center axis CA, which extends parallel with the axial direction A1.

As depicted in FIG. 10, the showerhead 300 includes a body 301, which can be formed by a stacked arrangement of a top plate 302 and a core plate 303. In some embodiments, the top plate 302 can be diffusion bonded to the core plate 303 to form the body 301. In other embodiments, the body 301 can be formed as a unitary, monolithic component, e.g., by an additive manufacturing process.

Much like the dual-channel radial flow showerhead 200 of FIGS. 2 through 9B, the dual-channel cross flow showerhead 300 of FIG. 10 has two gas channels, including a first gas channel 304 and a second gas channel 305. A first gas G1 can flow along the first gas channel 304 and a second gas G2 can flow along the second gas channel 305. The first and second gas channels 304, 305 are fluidly isolated from one another.

The first gas channel 304 formed by the body 301 includes a first stage (or delivery stage) and a second stage (or distribution stage). Generally, in the first stage of the first gas channel 304, the first gas G1 is delivered to chord-extending passages 306 formed by chord-extending ribs 307 of the body 301. In the second stage of the first gas channel 304, the first gas G1 can flow along the chord-extending passages 306. A first portion of the first gas G1 flowing along the chord-extending passages 306 can flow through a plurality of distribution holes 308 in fluid communication with respective ones of the chord-extending passages 306 (see FIG. 11). In this way, the first gas G1 can be distributed, e.g., into a processing chamber arranged below the showerhead 300 for processing of a substrate. Further, a second portion of the first gas G1 flowing along the chord-extending passages 306 can flow to respective outlets of the chord-extending passages 306 and can ultimately be exhausted from the showerhead 300.

More particularly, for the first stage, the first gas channel 304 includes an inlet 309 that allows the first gas G1 to flow into the showerhead 300. The first gas G1 entering the showerhead 300 can split into a first delivery portion and a second delivery portion, with the first delivery portion flowing along a first delivery passage 310 and the second delivery portion flowing along a second delivery passage 311. Accordingly, a recursion or splitting of the first gas G1 takes place at the intersection of the inlet 309 and the first and second delivery passages 310, 311.

The first delivery passage 310 can deliver the first delivery portion of the first gas G1 to a first inlet plenum 312 while the second delivery passage 311 can deliver the second delivery portion of the first gas G1 to a second inlet plenum 313. The first and second inlet plenums 312, 313 have wider radial widths than their respective first and second delivery passages 310, 311. The first and second inlet plenums 312, 313 each extend circumferentially, e.g., between eighty and ninety degrees (80-90°). The first and second delivery passages 310, 311 and the first and second inlet plenums 312, 313 are each formed by or recessed into a top surface 314 of the core plate 303. When the top plate 302 is disposed on the core plate 303, the first and second delivery passages 310, 311 and the first and second inlet plenums 312, 313 are enclosed.

For the second stage of the first gas channel 304, the first gas G1 can flow from one of the inlet plenums 312, 313 into one of the chord-extending passages 306. For the illustrated embodiment of FIG. 10, the chord-extending ribs 307 are arranged so that the chord-extending passages 306 are parallel chord-extending passages. Further, each chord-extending passage 306 has a passage inlet 315 and a passage outlet 316. Accordingly, the first gas G1 can flow from one of the inlet plenums 312, 313 into the chord-extending passages 306 through their respective passage inlets 315 and can flow or “cross flow” along the chord-extending passages 306 toward their respective passage outlets 316.

With reference now to FIGS. 10 and 11, at least a portion of the first gas G1 flowing along the chord-extending passages 306 can flow through the distribution holes 308 in fluid communication with the chord-extending passages 306. As depicted in FIG. 11, the distribution holes 308 extend from the chord-extending passages 306 to a bottom surface 317 of the body 301. In this way, the first gas G1 can exit the showerhead 300 through the distribution holes 308 and can, e.g., be distributed within a processing chamber arranged below the showerhead 300.

In some embodiments, the distribution holes 308 can have their respective long axes extending parallel with the axial direction A1, e.g., as shown in FIG. 11. In other embodiments, the distributions holes 308 can be angled with respect to the axial direction A1. That is, the long axes the distribution holes 308 can be angled with respect to the axial direction A1. In some embodiments, the distribution holes 308 can vary in diameter along their respective long axes. In other embodiments, the distribution holes 308 can have a same or constant diameter along their respective long axes.

With reference again to FIG. 10, at least a portion of the first gas G1 flowing along the chord-extending passages 306 can flow past the distribution holes 308 and can exit the chord-extending passages 306 by way of their respective passage outlets 316. The first gas G1 can exit the chord-extending passages 306 into an exhaust plenum 321, which can collect the first gas G1 and direct the first gas G1 to an outlet 322 of the first gas channel 304. The first gas G1 can be exhausted from the showerhead 300 by way of the outlet 322.

The second gas channel 305 along which the second gas G2 flows is collectively formed by through holes 323 defined by the body 301. As depicted in FIG. 11, the through holes 323 extend from the top surface 314 of the body 301 to the bottom surface 317 of the body 301. The through holes 323 can be arranged concentrically around the center axis CA of the body 301 and can be aligned with, and can extend through, each of the chord-extending ribs 307. The through holes 323 can each have an inlet 324 and an outlet 325 as shown in FIG. 11.

In some embodiments, the through holes 323 can have a same or constant diameter along their respective long axes, e.g., as shown in FIG. 11. In other embodiments, the through holes 323 can vary in diameter along their respective long axes. Further, in some embodiments, the through holes 323 can have their respective long axes extending parallel with the axial direction A1, e.g., as shown in FIG. 11. In other embodiments, at least a portion of each one of the through holes 323 can be angled with respect to the axial direction A1.

To conclude, with reference generally to FIGS. 10 and 11, the cross flow, dual-channel showerhead 300 disclosed herein can provide certain advantages and benefits. For instance, while keeping the reactants of the first and second gases G1, G2 separate in their respective first and second gas channels 304, 305, the chord-extending passages 306 of the first gas channel 304 allow the first gas G1 to “cross flow” from one side of the body 301 to the other in a streamlined manner, with the first gas G1 only needing to flow along respective parallel chords of the body 301 to distribute the first gas G1 to the distribution holes 308. The first gas G1 can flow along a plurality of parallel chords in a uniform manner to the distribution holes 308, which in turn allows for, e.g., uniform distribution of the first gas G1 to the processing chamber. Moreover, when pulsing and switching the first and second gases G1, G2, the first gas G1 can be pulsed into the showerhead 300, and the streamlined chord-extending passages 306 can shorten the distance the first gas G1 flows through the showerhead 300 to the processing chamber, compared to conventional showerheads. And, when the second gas G2 is to be pulsed, the first gas G1 within the first gas channel 304 can be discharged therefrom in a relatively short time period (e.g., by coordinating opening and closing of inlet and outlet valves), due to the streamlined chord-extending passages 306 that offer relatively short fluid paths for the first gas G1 to flow. Once the first gas G1 is discharged, the second gas G2 can be directed through the through holes 323, which are also streamlined due to their direct region-to-chamber, axially-extending arrangement. The second gas G2 directed through the through holes 323 can flow into a processing chamber, where the precursors thereof can be used to process the substrate. The through holes 323 can offer high radical transport with high ion blocking efficiency. The switching and pulsing of the first and second gases G1, G2 can continue in the manner described above.

FIG. 12 is a flow diagram for an example method 400, according to one or more embodiments of the disclosure.

At 402, the method 400 can include flowing a first gas through a first gas channel to a processing chamber of a semiconductor processing system, the first gas channel being defined by a body of a showerhead.

In some implementations, the showerhead is a radial flow, dual-channel showerhead. In such implementations, in flowing the first gas through the first gas channel at 402, the first gas is injected into a distribution cavity defined by the body and the injected first gas flows radially along a plurality of radially-extending passages defined by radially-extending ribs of the body, with at least a portion of the first gas flowing radially along the radially-extending passages flowing through distribution holes and to the processing chamber. In some further implementations, the first gas channel can be defined, in part, by a recursive network of delivery channels. In such further implementations, the first gas can be delivered to injection holes in fluid communication with the distribution cavity. In this way, the first gas can be injected into the distribution cavity via the injection holes. The injection holes can be located in a centrally-located region of the body, e.g., in a circumferential arrangement. Once injected into the distribution cavity, the first gas can flow radially in all radial directions (or all available radially-extending passages) from the centrally-located region, including radially outward from the centrally-located region as well as radially inward toward a center axis of the body.

In some implementations, the showerhead is a cross flow, dual-channel showerhead. In such implementations, in flowing the first gas through the first gas channel at 402, the first gas is delivered to chord-extending passages defined by chord-extending ribs of the body. At least a portion of the first gas flowing along the chord-extending passages can flow through distribution holes and to the processing chamber. In some further implementations, the first gas channel can be defined, in part, by a recursive network of delivery channels and plenums. The chord-extending ribs can be arranged parallel to one another along different chords of the body.

At 404, the method 400 can include flowing a second gas through a second gas channel from a remote plasma region to the processing chamber, the second gas channel being defined collectively by through holes formed by the body. The first and second gas channels are fluidly isolated from one another.

In some implementations, the first and second gases can be pulsed in an alternating manner at 402 and 404, e.g., with the first gas being pulsed at 402 so that the first gas is distributed into the processing chamber via the first gas channel, with the semiconductor processing system then switching to pulsing the second gas at 404 so that the second gas is distributed into the processing chamber via the second gas channel, with the semiconductor processing system then switching to pulsing the first gas at 402, and switching to pulsing the second gas at 404, and so on. In some iterations of the pulsing and switching at 402 and 404, prior to flowing the second gas through the second gas channel at 404, the method 400 can include discharging the first gas from the first gas channel, e.g., by coordinating opening and closing of inlet and outlet valves to pump out the first gas. The radially-extending passages or chord-extending passages, depending on the showerhead configuration, can provide a relatively streamlined flowpath for the first gas to be exhausted from the showerhead, compared to conventional showerheads, which can provide for fast gas switching.

While the foregoing is directed to embodiments of the present disclosure, other and further embodiments of the disclosure may be devised without departing from the basic scope thereof, and the scope thereof is determined by the claims that follow.

What is claimed is:

1. A showerhead for use in a semiconductor processing chamber, comprising:
a body having a top surface and a bottom surface, and wherein:
the body defines a first gas channel formed, at least in part, by injection holes in fluid communication with a distribution cavity in which a plurality of radially-extending ribs of the body define a plurality of radially-extending passages, and wherein a first gas is flowable along the first gas channel so that the first gas injected through the injection holes and into the distribution cavity flows radially along the plurality of radially-extending passages and so that at least a portion of the first gas flowing along the plurality of radially-extending passages flows through distribution holes extending to the bottom surface,
the body defines a second gas channel formed by a plurality of through holes that extend from the top surface to the bottom surface so that a second gas is flowable therethrough, and
the first and second gas channels are fluidly isolated from one another within the showerhead.

2. The showerhead of claim 1, wherein the body is formed by a stacked arrangement of a top plate, a bottom plate, and a core plate disposed between the top plate and the bottom plate, wherein the top plate is bonded to the core plate and the bottom plate is bonded to the core plate.

3. The showerhead of claim 1, wherein the first gas channel defined by the body is formed, at least in part, by an inlet plenum and delivery passages including, a first delivery passage and a second delivery passage both in fluid communication with the inlet plenum,
wherein the first delivery passage receives a first portion of the first gas from the inlet plenum and splits the first portion into first and second injection portions by way of a first splitter rib of the body, and
wherein the second delivery passage receives a second portion of the first gas from the inlet plenum and splits the second portion into third and fourth injection portions by way of a second splitter rib of the body.

4. The showerhead of claim 3, wherein the injection holes are arranged in a first set, a second set, a third set, and a fourth set, and wherein the injection holes of the first set are arranged to receive the first injection portion of the first gas, the injection holes of the second set are arranged to receive the second injection portion of the first gas, the injection holes of the third set are arranged to receive the third injection portion of the first gas, and the injection holes of the fourth set are arranged to receive the fourth injection portion of the first gas.

5. The showerhead of claim 1, wherein the injection holes are arranged circumferentially around a center axis defined by the showerhead.

6. The showerhead of claim 1, wherein the first gas channel defined by the body is formed, at least in part, by recursive delivery passages, and wherein the recursive delivery passages are axially spaced from the distribution cavity and the injection holes extend axially between the recursive delivery passages and the distribution cavity and provide fluid communication therebetween.

7. The showerhead of claim 1, wherein the radially-extending ribs are arranged in an annular array around a center axis defined by the showerhead.

8. The showerhead of claim 1, wherein the radially-extending ribs are:
circumferentially spaced from one another,
have an axial height spanning an axial height of the distribution cavity, and
have their respective long axes extending radially with respect to a center axis defined by the showerhead.

9. The showerhead of claim 1, wherein the radially-extending ribs are arranged so that the first gas is split into separate portions at least once in each of the radially-extending passages.

10. The showerhead of claim 1, wherein, for at least one radially-extending passage of the radially-extending passages, at least one of the distribution holes in fluid communication with the at least one radially-extending passage is arranged radially inward of the injection holes with respect to a center axis defined by the showerhead and at least one of the distribution holes in fluid communication with the at least one radially-extending passage is arranged radially outward of the injection holes with respect to the center axis.

11. The showerhead of claim 1, wherein the distribution cavity has an exhaust plenum extending circumferentially around the radially-extending ribs and has a radial width defined between a wall of the body defining an outer perimeter of the distribution cavity and radially outermost ends of the radially-extending ribs.

12. The showerhead of claim 11, wherein the body defines an exhaust passage in fluid communication with the exhaust plenum, and wherein a portion of the first gas flowing radially along the radially-extending passages flows to the exhaust plenum and into the exhaust passage.

13. The showerhead of claim 1, wherein the through holes extend, at least in part, through the radially-extending ribs.

14. The showerhead of claim 1, wherein the injection holes are arranged in an injection region, which is a central region of the body encompassing an area extending radially outward from a center axis defined by the showerhead and swept by a radius that is less than one sixth a radius of the body.

15. A semiconductor processing system, comprising:
a remote plasma region;
a processing chamber; and
a showerhead at least partially defining the remote plasma region and at least partially defining the processing chamber, the showerhead comprising:
a body having a top surface and a bottom surface, and wherein:
the body defines a first gas channel formed, at least in part, by injection holes in fluid communication with a distribution cavity in which a plurality of radially-extending ribs of the body define a plurality of radially-extending passages, and wherein a first gas is flowable along the first gas channel so that the first gas injected through the injection holes and into the distribution cavity flows radially along the plurality of radially-extending passages and so that at least a portion of the first gas flowing along the plurality of radially-extending passages flows through distribution holes into the processing chamber,
the body defines a second gas channel formed by a plurality of through holes that extend from the top surface to the bottom surface so that a second gas is flowable therethrough from the remote plasma region into the processing chamber, and
the first and second gas channels are fluidly isolated from one another within the showerhead.

16. The semiconductor processing system of claim 15, wherein the first gas channel defined by the body is formed, at least in part, by a recursive network of delivery passages that deliver the first gas to the injection holes, which are arranged circumferentially-spaced from one another around a center axis defined by the showerhead.

17. The semiconductor processing system of claim 15, wherein the injection holes are arranged in an injection region, which is a central region of the body encompassing an area extending radially outward from a center axis defined by the showerhead and swept by a radius that is less than one sixth a radius of the body.

18. The semiconductor processing system of claim 15, wherein, for at least one radially-extending passage of the radially-extending passages, at least one of the distribution holes in fluid communication with the at least one radially-extending passage is arranged radially inward of the injection holes with respect to a center axis defined by the showerhead and at least one of the distribution holes in fluid communication with the at least one radially-extending passage is arranged radially outward of the injection holes with respect to the center axis.

19. The semiconductor processing system of claim 15, wherein the through holes extend, at least in part, through the radially-extending ribs.

20. A showerhead for use in a semiconductor processing chamber, comprising:
a body having a top surface and a bottom surface, and wherein:
the body defines a first gas channel formed, at least in part, a plurality of chord-extending passages defined by a plurality of chord-extending ribs of the body, wherein a first gas is flowable along the first gas channel so that the first gas delivered to the chord-extending passages flows chordwise along the plurality of chord-extending passages and so that at least a portion of the first gas flowing along the chord-extending passages flows through distribution holes extending to the bottom surface,
the body defines a second gas channel formed by a plurality of through holes that extend from the top surface to the bottom surface so that a second gas is flowable therethrough, and
the first and second gas channels are fluidly isolated from one another within the showerhead.
